(19) United States
(12) Patent Application Publication
(10) Pub. No.: US 2021/0320232 A1
(43) Pub. Date: Oct. 14, 2021

(54) Optoelectronic Component and Method for Producing an Optoelectronic Component

(71) Applicant: OSRAM OLED GmbH, Regensburg (DE)

(72) Inventors: Ivar Tangring, Regensburg (DE); Susanne Brunner, Regensburg (DE)

(21) Appl. No.: 17/273,773

(22) PCT Filed: Aug. 27, 2019
(86) PCT No.: PCT/EP2019/072862

§ 371 Date: Mar. 5, 2021

(30) Foreign Application Priority Data
Sep. 10, 2018 (DE) 10 2018 121 988.1

(51) Int. Cl. H01L 33/50; H01L 33/62; H01L 33/60

(52) U.S. Cl. CPC H01L 33/505; H01L 33/62; H01L 2933/0058; H01L 2933/0041; H01L 33/60

(57) ABSTRACT

In an embodiment an optoelectronic component includes a radiation-emitting semiconductor chip configured to emit electromagnetic primary radiation from a radiation exit surface, a conversion element configured to convert the primary radiation into electromagnetic secondary radiation, wherein the conversion element has a frame which covers side surfaces of a conversion segment, and wherein the frame is formed reflective, and a bonding agent fixing the conversion element on the radiation exit surface of the semiconductor chip, wherein a contact point of the semiconductor chip projects beyond the conversion element in an edge region of the semiconductor chip in lateral directions, and wherein the bonding agent covers an outer surface of the frame and the contact point of the semiconductor chip in places.

This patent application is a national phase filing under section 371 of PCT/EP2019/072862, filed Aug. 27, 2019, which claims the priority of German patent application 102018121988.1, filed Sep. 10, 2018, each of which is incorporated herein by reference in its entirety.

### TECHNICAL FIELD

An optoelectronic component is specified. In addition, a method for producing an optoelectronic component is specified.

### SUMMARY

Embodiments provide an optoelectronic component having a particularly good light extraction. Further embodiments provide a method for producing such an optoelectronic component.

According to at least one embodiment, the optoelectronic component comprises a radiation-emitting semiconductor chip emitting electromagnetic primary radiation from a radiation exit surface during operation. Preferably, the radiation exit surface is arranged parallel to a top surface of the semiconductor chip. Preferably, the top surface of the semiconductor chip forms the radiation exit surface. Alternatively, it is possible that an edge region of the top surface of the semiconductor chip is not part of the radiation exit surface. The electromagnetic primary radiation emitted from the radiation-emitting semiconductor chip can be, for example, near-ultraviolet radiation, visible light, and/or near-infrared radiation.

The optoelectronic component preferably has a main extension plane. The vertical direction extends perpendicular to the main extension plane, and the lateral direction extends parallel to the main extension plane.

The radiation emitting semiconductor chip is, for example, a surface emitter in which the majority of the emitted primary radiation, for example, more than 80% of a radiation power, exits through the radiation exit surface comprised by a first main surface of the radiation emitting semiconductor chip.

The surface emitter can be, for example, a thin film chip. Thin film chips typically have an epitaxially grown semiconductor layer sequence with an active primary radiation generating region deposited on a carrier element different than the growth substrate for the semiconductor layer sequence. Particularly preferably, a mirror layer is arranged between the semiconductor layer sequence and the carrier element, which directs primary radiation of the active zone to the first major surface. Thin film chips generally do not emit the electromagnetic primary radiation generated in the active region during operation via the side surfaces of the carrier element, but have a substantially Lambertian radiation pattern. For example, the thin film chip has an electrical contact at the first major surface.

Further, the radiation emitting semiconductor chip can be a substrate-less semiconductor chip that is free of a carrier element and a growth substrate. For example, the substrate-less semiconductor chip has a thickness between 5 micrometers and 50 micrometers, inclusive.

Further, the radiation emitting semiconductor chip can be a volume emitting semiconductor chip that emits the emitted primary radiation not only over the first major surface but also over at least one side surface. For example, in a volume-emitting semiconductor chip, at least 30% radiation power of the emitted primary radiation exits through the at least one side surface.

A volume-emitting semiconductor chip preferably has a substrate, on its first major surface a semiconductor layer sequence is grown typically epitaxially having an active region that generates the electromagnetic primary radiation during operation. For example, the substrate can comprise or be made of any of the following materials: Sapphire, Silicon Carbide. If the substrate is a sapphire substrate, two electrical contacts of the volume emitting semiconductor chip are preferably arranged on the first major surface of the semiconductor chip. The volume emitting semiconductor chip can be electrically contacted, for example, by means of wire connections via the two electrical contacts.

According to at least one embodiment, the optoelectronic component comprises a conversion element converting primary radiation into electromagnetic secondary radiation. The conversion element comprises a conversion segment comprising, for example, a first matrix material in which phosphor particles are incorporated. The first matrix material is, for example, a sol-gel glass. The first matrix material can be, for example, a resin such as an epoxy or a silicone or a mixture of these materials. Preferably, the phosphor particles thereby impart the wavelength-converting properties to the conversion element.

For the phosphor particles, for example, one of the following materials is suitable: Rare earth doped garnets, rare earth doped alkaline earth sulfides, rare earth doped thiogallates, rare earth doped aluminates, rare earth doped silicates, rare earth doped orthosilicates, rare earth doped chlorosilicates, rare earth doped alkaline earth silicon nitrides, rare earth doped oxynitrides, rare earth doped aluminum oxynitrides, rare earth doped silicon nitrides, rare earth doped sialons, quantum dot phosphors.

The phosphor particles can be used without the first matrix material. In this case, the phosphor particles are preferably directly deposited on a transparent carrier. Furthermore, the first matrix material in which phosphor particles are incorporated can be applied to the transparent carrier. In this case, the first matrix material with the phosphor particles is preferably formed as a thin layer. The thin layer preferably has a thickness that is at most 50 micrometers. Particularly preferably, the thickness of the thin layer is at most 30 micrometers.

The transparent carrier is generally the mechanically supporting component of the conversion segment. The transparent carrier is preferably formed to be transparent to electromagnetic primary and electromagnetic secondary radiation, and preferably comprises or consists of a glass.

According to at least one embodiment, the conversion element comprises a frame covering side surfaces of a conversion segment. Preferably, the frame completely covers the side surfaces of the conversion segment. The side surfaces of the conversion segment connect a top surface and a bottom surface of the conversion segment. Preferably, the bottom surface of the conversion segment terminates flush with a bottom surface of the frame. Further, the top surface of the conversion segment preferably terminates flush with a top surface of the frame. A top surface and a bottom surface of the conversion element are thus preferably formed substantially planar. Substantially planar means that the top surface and/or the bottom surface of the conversion element can have an unevenness due to manufacturing tolerances. The unevenness in the form of elevations and depressions can have a maximum extent in the vertical direction of at most 10 micrometers. Preferably, the maximum extent of the unevenness in the vertical direction is at most 5 micrometers.

Preferably, the frame is formed reflective, particularly preferably diffusely reflective. According to at least one embodiment, the frame is diffusely reflective for primary radiation emitted by the semiconductor chip. The frame preferably has a reflectivity of at least 90% for the electromagnetic primary radiation emitted by the radiation emitting semiconductor chip and the electromagnetic secondary radiation converted by the conversion segment.

The frame comprises, for example, a second matrix material in which reflective particles are incorporated. The second matrix material is, for example, a sol-gel glass. The second matrix material can be, for example, a resin such as an epoxy, a silicone, a ceramic, a glass, or a mixture of these materials. Furthermore, the second matrix material preferably has a comparatively low refractive index. Preferably, the reflective particles are formed by TiO₂ particles. For example, the reflective particles comprise or are formed by any of the following materials: TiO₂, SiO₂, MfO₂.

According to at least one embodiment, the optoelectronic component comprises a bonding agent to fix the conversion element to the radiation exit surface of the semiconductor chip. The bonding agent is preferably arranged between the conversion element and the radiation emitting semiconductor chip. The bonding agent mediates a connection between the conversion element and the radiation-emitting semiconductor chip. This connection preferably mechanically fixes the conversion element to the radiation-emitting semiconductor chip in a stable manner. Further, this connection is preferably thermally conductive.

The bonding agent preferably comprises or consists of a radiation-transmissive material. Particularly preferably, the material of the bonding agent is configured to transmit electromagnetic primary radiation.

According to one embodiment, the bonding agent comprises or consists of a third matrix material. The matrix material can be a resin, such as an epoxy or a silicone. Preferably, the bonding agent is formed by a clear silicone.

Preferably, the third matrix material has a transmissivity of at least 90% for electromagnetic primary radiation emitted by the radiation-emitting semiconductor chip.

According to at least one embodiment, the bonding agent covers an outer surface of the frame in places. The outer surface of the frame facing away from the conversion segment is thus preferably only partially covered by the bonding agent.

According to one embodiment, the optoelectronic component comprises a radiation emitting semiconductor chip emitting electromagnetic primary radiation from a radiation exit surface during operation and a conversion element converting primary radiation into electromagnetic secondary radiation, the conversion element has a frame that covers side surfaces of a conversion segment and is reflective. Further, in this embodiment, the optoelectronic component comprises a bonding agent with which the conversion element is fixed on the radiation exit surface of the semiconductor chip, wherein the bonding agent covering an outer surface of the frame in places.

One idea of the optoelectronic component described herein is to use, inter alia, a conversion element comprising a frame and a conversion segment, wherein the frame is formed reflective and surrounds side surfaces of the conversion segment. By means of the frame, the electromagnetic primary and secondary radiation that is emitted, for example, from the side surfaces of the conversion segment is reflected again and enters the conversion segment once more. There, the remaining primary radiation is converted again. Furthermore, the primary and secondary radiations are preferably directed in direction of the top surface of the conversion segment by means of the frame. This advantageously increases the light extraction of the optoelectronic component.

Furthermore, the conversion element is preferably fixed to the radiation-emitting semiconductor chip by means of a bonding agent. Excess material of the bonding agent is preferably arranged on the outer surfaces of the frame and at least partially covers the outer surfaces. Generally, a bonding agent is a good light guide for the emitted primary and secondary radiation. However, since a direct optical path of the primary and secondary radiation from the conversion segment is advantageously interrupted by the frame, light conduction of the excess material of the bonding agent on the outer surfaces of the frame is suppressed. Thus, the light extraction and the efficiency of the optoelectronic component can be further improved.

According to at least one embodiment, the radiation-emitting semiconductor chip is laterally surrounded by a cover layer having a top surface. The cover layer comprises, for example, a fourth matrix material in which reflective particles are incorporated. The fourth matrix material can be, for example, a resin such as an epoxy or a silicone or a mixture of these materials. The reflective particles are, for example, TiO₂ particles. Preferably, the cover layer is diffusely reflective.

Preferably, the top surface of the cover layer terminates flush with the radiation exit surface. The top surface of the cover layer thus preferably lies in a common plane with the radiation exit surface of the radiation-emitting semiconductor chip. Alternatively, the top surface of the cover layer cannot be located in the common plane in the vertical direction. In this case, the radiation exit surface can project beyond the covering surface of the cover layer in the vertical direction. Alternatively, the top surface of the cover layer can project beyond the radiation exit surface in the vertical direction.

According to at least one embodiment, the bonding agent covers a side surface of the frame and a top surface of the cover layer in places. The side surface of the frame facing away from the conversion segment is preferably covered by the bonding agent in the vertical direction up to a height. The height, up to which the bonding agent covers the side surface of the frame, is preferably less than a height of the frame. The height of the frame is thereby the maximum extension in the vertical direction.

The side surface of the frame can be completely covered with the bonding agent. Alternatively, it is possible that the side surface of the frame is at most 80% covered with the bonding agent. Preferably, the side surface of the frame is at most 60% covered with the bonding agent.

Furthermore, the top surface of the cover layer can be covered with the bonding agent in the region around the frame. If a ratio of an area of the top surface of the cover layer to an area of the top surface of the semiconductor chip is comparatively large, a majority of the top surface of the cover layer is preferably free of the bonding agent. In this case, the bonding agent preferably covers at most 5% of the top surface of the cover layer. Alternatively, it is possible that a ratio of the area of the top surface of the cover layer to the area of the top surface of the semiconductor chip is comparatively small. In this case, it is possible that the top surface of the cover layer is completely covered by the bonding agent.

The bonding agent is preferably in direct contact with the side surface of the frame and the top surface of the cover layer. The direct contact of the bonding agent to the side surface of the frame and the top surface of the cover layer improves the adhesion between the conversion element and the radiation-emitting semiconductor chip. The connection between the radiation-emitting semiconductor chip and the conversion element is thus particularly mechanically stable.

According to at least one embodiment, the bonding agent covers a bottom surface of the frame and a side surface of the semiconductor chip in places. Preferably, the bonding agent completely covers the bottom surface of the frame. Further, it is possible that the bonding agent covers the bottom surface of the frame to at most 80%.

Preferably, the side surface of the semiconductor chip is only partially covered by the bonding agent. A region of the side surface of the semiconductor chip is preferably free of the bonding agent starting from a main surface of the semiconductor chip opposite to the radiation exit surface. Preferably, at most 80% of the side surface of the semiconductor chip is covered with the bonding agent. Particularly preferably, the side surface of the semiconductor chip is at most 60% covered with the bonding agent.

Furthermore, the bonding agent is preferably in direct contact with the side surface of the semiconductor chip. The direct contact of the bonding agent to the side surface of the semiconductor chip further improves the adhesion between the conversion element and the radiation emitting semiconductor chip.

According to at least one embodiment, a contact point of the semiconductor chip projects beyond the conversion element in an edge region of the semiconductor chip in the lateral direction. By means of the contact point, the semiconductor chip is preferably contactable and energizable.

According to at least one embodiment, the frame laterally projects beyond the semiconductor chip in an opposite edge region. In the opposite edge region, the bonding agent preferably covers the bottom surface of the frame and the side surface of the semiconductor chip in places. Furthermore, the radiation exit surface in the opposite edge region preferably projects beyond the bottom surface of the conversion segment. By this arrangement, an optical path from the conversion segment to the bonding agent at the bottom surface of the frame and at the side surface of the semiconductor chip is advantageously interrupted to a large extent.

In the case where the edge region of the top surface of the semiconductor chip is not part of the radiation exit surface, it is possible that the semiconductor chip projects beyond the frame. Alternatively, it is possible that the side surface of the semiconductor chip and the side surface of the frame terminate flush with one another. Preferably, the frame covers the edge region of the top surface of the semiconductor chip that is not part of the radiation exit surface.

According to at least one embodiment, the bonding agent covers a side surface of the frame and the contact point of the semiconductor chip in places. Preferably, at most 80% of the side surface of the frame in the region of the contact point is covered with the bonding agent. Particularly preferably, the side surface in the region of the contact point of the frame is at most 60% covered with the bonding agent.

According to at least one embodiment, a potting embeds the semiconductor chip and/or the conversion element. If the optoelectronic component has the cover layer, the cover layer preferably surrounds only the semiconductor chip and the potting embeds only the conversion element. If the optoelectronic component does not have a cover layer, the potting preferably embeds the semiconductor chip and the conversion element.

For example, the potting has a fifth matrix material. The fifth matrix material can be, for example, a resin such as an epoxy or a silicone, or a mixture of these materials.

Preferably, reflective particles are incorporated into the fifth matrix material. Preferably, the reflective particles are formed by TiO₂ particles. Thus, the potting preferably exhibits a reflectivity of at least 60% for the electromagnetic primary radiation emitted by the radiation emitting semiconductor chip and the electromagnetic secondary radiation converted by the conversion segment. Particularly preferably, the potting has a reflectivity of at least 80% for the electromagnetic primary radiation and the electromagnetic secondary radiation. In this case, the potting preferably has a thickness that is between 50 micrometers and 100 micrometers, inclusive.

Furthermore, the potting is preferably comparatively hard and can thus be particularly mechanically stable. As a result, the potting can protect the semiconductor chip and the conversion element particularly well from external influences.

According to at least one embodiment, the cover layer is formed diffusely reflective for primary radiation emitted by the semiconductor chip. Primary and secondary radiation reflected at the diffusely reflecting frame and at the diffusely reflecting cover layer preferably exhibit a substantially Lambertian beam characteristic. The diffusely reflected primary and secondary radiations advantageously appear as equally bright to an external observer regardless of a viewing direction.

According to at least one embodiment, an outer surface of the bonding agent has a convex or concave shape. The outer surface of the bonding agent is the outer surface of the bonding agent facing away from the frame and the cover layer. Further, the outer surface of the bonding agent can be the outer surface facing away from the frame and the side surface of the semiconductor chip. Preferably, the outer surface of the bonding agent has a convex shape. Alternatively, the outer surface of the bonding agent has a concave shape or a free shape.

According to at least one embodiment, the bonding agent between the conversion element and the semiconductor chip has a thickness of at most 3 micrometers. In particular preferably, the bonding agent between the conversion element and the semiconductor chip has the thickness of at most 1 micrometer. For example, the thickness of the conversion element is not formed to be constant. The bottom surface of the conversion element can have elevations and depressions due to manufacturing. In particular, it is possible that the bottom surface of the conversion element is in direct contact with the radiation exit surface of the semiconductor chip in the region of the elevations.

According to at least one embodiment, the frame has a width of at least 20 micrometers and at most 50 micrometers.

According to at least one embodiment, the semiconductor chip is arranged on a connection carrier. The connection carrier is formed or comprises, for example, a metallic and/or ceramic material. The connection carrier is or comprises, for example, a circuit board or a lead frame.

According to at least one embodiment, the contact point is contacted by means of a wire connection. The contact point is preferably formed as a bond pad, which is preferably electrically conductively connected to the wire connection. The bond pad preferably comprises or consists of a metal. Preferably, the wire connection electrically conductively connects the contact point to the connection carrier. By means of the wire connection and the contact point, the radiation emitting semiconductor chip can generally be energized.

Further, the bonding agent can partially cover the contact point. The wire connection arranged on the contact point can also be partially covered by the bonding agent. The contact point and the wire connection can each be in direct contact with the bonding agent.

A method for producing an optoelectronic component is further disclosed, by which an optoelectronic component described herein can be produced. All features and embodiments disclosed in connection with the optoelectronic component are therefore also applicable in connection with the method, and vice versa.

According to at least one embodiment of the method, a radiation-emitting semiconductor chip is provided emitting electromagnetic primary radiation from a radiation exit surface during operation.

According to at least one embodiment of the method, a conversion element is provided converting primary radiation to electromagnetic secondary radiation, wherein the conversion element comprises a frame that covers side surfaces of a conversion segment. A material of the conversion segment is initially preferably in a flowable form. For example, the material of the conversion segment has an initially fluid resin such as silicone as a matrix material in which phosphor particles are incorporated. If the conversion segment material is in a flowable or liquid form, it is generally cured after being applied to form the conversion segment.

Further, the conversion segment can be disposed on a transparent carrier. The conversion segment can thus be arranged on the transparent carrier as a comparatively thin layer, wherein the transparent carrier is the mechanically supporting component of the composite of conversion segment and transparent carrier. In this case, the conversion element is formed by the conversion segment, the transparent carrier and the frame. In this case, the frame completely covers the side surfaces of the conversion segment and the transparent carrier.

Furthermore, a material of the frame is preferably in a flowable form when applied. For example, the material of the frame has an initially fluid resin or silicone into which reflective particles are incorporated. If the material of the frame is in a flowable or liquid form when applied, it is generally cured after being applied to form the frame.

According to at least one embodiment of the method, a bonding agent is applied to the radiation exit surface of the semiconductor chip. Preferably, the bonding agent is in a flowable form when applied. For example, the bonding agent is applied to the radiation exit surface of the semiconductor chip in the form of a droplet.

According to at least one embodiment of the method, the conversion element is applied to the bonding agent, wherein the bonding agent is partially displaced by the conversion element and covers an outer surface of the frame in places. For example, the conversion element is dipped centrally into the material of the bonding agent with a bottom side first and is preferably pressed against the radiation-emitting semiconductor chip with a constant pressure. The bonding agent is thereby partially displaced by the radiation exit surface of the radiation emitting semiconductor chip. In other words, preferably enough material of the bonding agent is applied so that when the conversion element is pressed onto the radiation exit surface, the material of the bonding agent is pushed from the volume of the conversion element to the outer surface of the frame facing away from the conversion segment.

One idea of the method described herein for producing an optoelectronic component is, inter alia, that due to the separation of the displaced bonding agent and the conversion segment by the frame, a precise adjustment of the amount of bonding agent to be applied to the radiation exit surface is not necessarily required. Furthermore, advantageously, comparatively much material of the bonding agent can be applied to the radiation exit surface to avoid voids between the conversion element and the semiconductor chip. In this way, a stable process is advantageously made possible.

A precise placement of the conversion element on the material of the bonding agent on the radiation exit surface of the semiconductor chip is made possible, for example, by a pick and place process.

In a subsequent step, the material of the bonding agent is cured to form the bonding agent. For example, the material of the bonding agent can be a UV-curable material. The advantage of using UV-curable material over a thermal-curable material is that there is no reduction in viscosity of the material of the bonding agent due to temperature effects during curing of the material of the bonding agent. UV-curable materials generally polymerize fully or partially at room temperature or slightly elevated temperatures.

According to at least one embodiment of the method, a potting material is applied over the semiconductor chip and/or the conversion element by film-assisted injection molding.

During foil assisted molding, a mold is generally used that has two mold halves or consists of two mold halves. At least one mold half is preferably lined with a film. The purpose of the film is to prevent the potting from adhering to the mold and to facilitate demolding of the workpiece. The workpiece to be overmolded, for example, the semiconductor chip with the conversion element, is placed in a cavity of the mold. The material that is to be injection molded around the workpiece is usually initially in solid form, for example as a tablet. The material that is to be injected is preferably brought into liquid form by heating and injected into the cavity. Then the material is cured and the part is demolded.

By using the highly reflective frame, film-assisted injection molding can thus advantageously be used to apply the potting. This allows the potting to be comparatively less reflective and to be applied in a simplified manner. Advantageously, a contrast ratio of the optoelectronic component is thus improved.

As an alternative to film-assisted injection molding, the potting can be applied by means of a molding process.

### BRIEF DESCRIPTION OF THE DRAWINGS

In the following, the optoelectronic component as well as the method described herein for producing an optoelectronic component are explained in more detail with reference to exemplary embodiments and the associated Figures.

FIGS. 1 and 2 show schematic sectional views of an optoelectronic component according to an exemplary embodiment;

FIG. 3 shows a schematic sectional view of an optoelectronic component according to an exemplary embodiment; and

FIGS. 4 to 6 each shows a schematic sectional view of method stages of the method for producing an optoelectronic component according to an exemplary embodiment.

### DETAILED DESCRIPTION OF ILLUSTRATIVE EMBODIMENTS

Identical, similar, or similar acting elements are provided with the same reference signs in the Figures. The Figures and the proportions of the elements shown in the Figures with respect to one another are not to be regarded as being to scale. Rather, individual elements can be shown exaggeratedly large for better representability and/or for better comprehensibility.

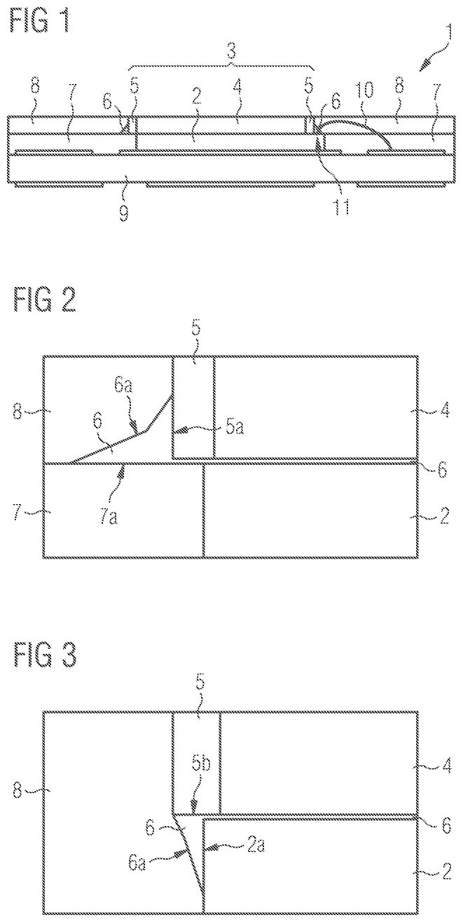

The optoelectronic component according to the exemplary embodiment of FIGS. 1 and 2 comprises a radiation-emitting semiconductor chip 2 and a conversion element 3 arranged thereon (FIG. 1). The conversion element 3 comprises a frame 5 and a conversion segment 4. The frame 5 completely covers side surfaces of the conversion segment 4. Preferably, the frame is formed completely circumferentially around the conversion segment 4.

In the present exemplary embodiment, the frame comprises a sol-gel glass or a glass in which TiO₂ particles are incorporated.

The present radiation-emitting semiconductor chip 2 is laterally surrounded by a cover layer 7. Further, the cover layer 7 has a top surface that terminates flush with a radiation exit surface of the radiation emitting semiconductor chip 2. The top surface of the cover layer 7 is in a common plane with the radiation exit surface of the radiation emitting semiconductor chip 2.

The cover layer 7 comprises, for example, an epoxy or a silicone in which reflective particles are incorporated. The reflective particles are, for example, TiO₂ particles. Preferably, the cover layer 7 is formed diffusely reflective, so that the cover layer 7 appears white.

The radiation-emitting semiconductor chip 2 and the cover layer 7 are arranged on a connection carrier 9. In this exemplary embodiment, the connection carrier comprises a metallic coating arranged on its outer surface in places. For example, the one metallic coating comprises or is formed of one of the following materials: Cu, Au. Further, a contact point 11 of the semiconductor chip 2 projects beyond the conversion element 3 in an edge region of the semiconductor chip 2 in a lateral direction. By means of the contact point 11, the semiconductor chip 2 is electrically conductively connected to the carrier 9 or to the metallic coating via a wire connection 10.

On the cover layer 7, a potting 8 is arranged to embed the conversion element 3 and completely cover the side surface of the frame 5a and an outer surface of the bonding agent 6a. Furthermore, the wire connection 10 and the contact point 11 are embedded and completely covered by the potting 8. Only a top surface of the conversion element 3 is free of the potting 8.

The potting 8 is formed of, for example, an epoxy or a silicone in which reflective particles are incorporated. The reflective particles are, for example, TiO₂ particles. Preferably, the potting 8 is formed diffusely reflective, so that the potting 8 appears white.

The conversion element 3 is arranged on the radiation-emitting semiconductor chip 2 by means of a bonding agent 6. In this regard, the bonding agent 6 covers a side surface of the frame 5a and the top surface of the cover layer 7a in places, respectively. Furthermore, the contact point 11 and the wire connection 10 are partially covered with the bonding agent 6.

The conversion element 3 is configured to convert primary radiation into electromagnetic secondary radiation. Furthermore, the frame 5 is formed to be reflective for primary and secondary radiation.

Generally, a bonding agent 6 is a good light guide for the emitted primary and secondary radiation. A direct optical path of the primary and secondary radiation from the conversion segment 4 to the excess material of the bonding agent 6 on the side surface of the frame 5a is advantageously interrupted by the frame 5. Thus, light conduction from the conversion segment 4 to the excess material of the bonding agent 6 at the side surface of the frame 5a is suppressed, and the light extraction and efficiency of the optoelectronic component 1 is improved.

An enlargement in the area of the bonding agent 6 on the side surface of the frame 5a is shown in FIG. 2. The bonding agent 6 is arranged between the conversion element 3 and the radiation-emitting semiconductor chip 2 and provides a mechanically stable connection. This connection mechanically fixes the conversion element 3 to the radiation-emitting semiconductor chip 2 in a stable manner.

The bonding agent 6 covers the side surface of the frame 5a in places. The side surface of the frame 5a facing away from the conversion segment is covered by the bonding agent 6 up to a height in the vertical direction. The height to which the bonding agent 6 covers the side surface of the frame is smaller than a height of the frame 5.

Further, the bonding agent 6 covers the top surface of the cover layer 7a in places. The top surface of the cover layer 7a is covered with the bonding agent 6 in the area around the frame 5, so that a large part of the top surface of the cover layer 7a is free of the bonding agent 6.

The bonding agent 6 is in direct contact with the side surface of the frame 5a and the top surface of the cover layer 7a. Further, the outer surface of the bonding agent 6a has a concave shape.

The optoelectronic component 1 according to the exemplary embodiment of FIG. 3 does not have a cover layer 7, in contrast to the optoelectronic component 1 according to the exemplary embodiment of FIG. 2. The conversion element 3 and the radiation-emitting semiconductor chip 2 are embedded by the potting. Only the top surface of the conversion element 3 is free of the potting 8.

The frame 5 projects beyond the radiation-emitting semiconductor chip 2 in lateral directions. The bonding agent 6 is arranged on a bottom surface of the frame 5b and a side surface of the semiconductor chip 2a in places. The bottom surface of the frame 5b is completely covered by the bonding agent.

The side surface of the semiconductor chip 2a is only partially covered by the bonding agent. A portion of the side surface of the semiconductor chip 2a is free of the bonding agent 6 starting from a main surface of the semiconductor chip 2 opposite to the radiation exit surface. Further, the bonding agent 6 is in direct contact with the side surface of the semiconductor chip 2a.

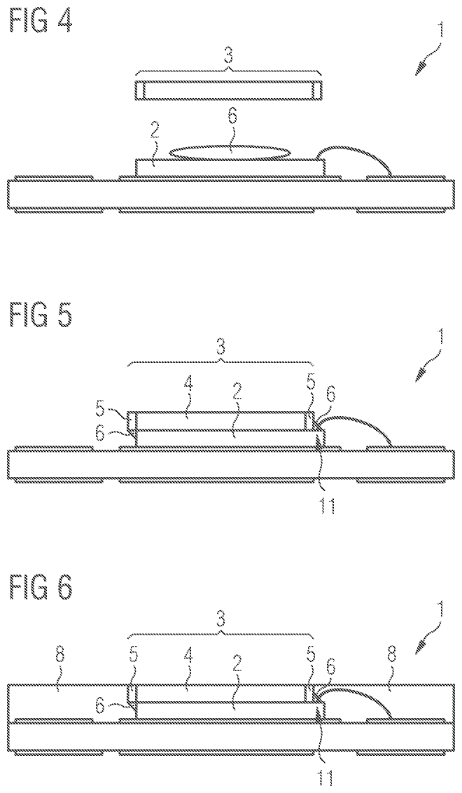

In connection with the exemplary embodiment of FIGS. 4 to 6, method stages for producing an optoelectronic component 1 are illustrated.

As shown in FIG. 4, the conversion element 3 and the radiation-emitting semiconductor chip 2 are provided separately. The bonding agent 6 is applied to the radiation exit surface of the radiation emitting semiconductor chip 2 in form of a droplet.

In a next method step, the conversion element 3 is applied to the bonding agent 6 (FIG. 5). The conversion element 3 is dipped centrally into the material of the bonding agent 6 with a bottom side first and is preferably pressed against the radiation-emitting semiconductor chip 2 with a constant pressure.

The bonding agent 6 is thus partially displaced by the conversion element 3 and is deposited in places in an edge region of the radiation-emitting semiconductor chip 2 in the region on the contact point 11. In addition, the displaced bonding agent 6 is deposited on the side surface of the frame 5a.

In an opposite edge region of the radiation-emitting semiconductor chip 2, the displaced bonding agent 6 is deposited on the side surface of the radiation-emitting semiconductor chip 2a in places. Further, the displaced bonding agent 6 covers the bottom surface of the frame 5b.

According to FIG. 6, a further method step is shown in which a potting agent 8 is applied over the semiconductor chip 2 and the conversion element 3. In the present case, the potting 8 is applied over the radiation-emitting semiconductor chip and the conversion element 3 by means of film-assisted injection molding. In this exemplary embodiment, no cover layer 7 surrounds the radiation-emitting semiconductor chip 2.

The invention is not limited to the exemplary embodiments by the description thereon. Rather, the invention encompasses any new feature as well as any combination of features which includes, in particular, any combination of features in the claims, even if this feature or this combination itself is not explicitly specified in the claims or exemplary embodiments.

1.-16. (canceled)

17. An optoelectronic component comprising:
a radiation-emitting semiconductor chip configured to emit electromagnetic primary radiation from a radiation emission surface;
a conversion element configured to convert the primary radiation into electromagnetic secondary radiation, wherein the conversion element has a frame covering side surfaces of a conversion segment and is reflective; and
a bonding agent fixing the conversion element on a radiation exit surface of the semiconductor chip,
wherein a contact point of the semiconductor chip projects beyond the conversion element in an edge region of the semiconductor chip in lateral directions, and
wherein the bonding agent covers an outer surface of the frame and the contact point of the semiconductor chip in places.

18. The optoelectronic component according to claim 17, wherein the semiconductor chip is laterally surrounded by a cover layer having a top surface.

19. The optoelectronic component according to claim 18, wherein the bonding agent covers a side surface of the frame and the top surface of the cover layer in places.

20. The optoelectronic component according to claim 18, wherein the cover layer is diffusely reflective for the primary radiation.

21. The optoelectronic component according to claim 17, wherein the bonding agent covers a bottom surface of the frame and a side surface of the semiconductor chip in places.

22. The optoelectronic component according to claim 17, wherein the frame projects beyond the semiconductor chip in an opposite edge region in lateral directions.

23. The optoelectronic component according to claim 17, wherein the bonding agent covers a side surface of the frame in places.

24. The optoelectronic component according to claim 17, further comprising a potting, wherein the potting embeds the semiconductor chip and/or the conversion element.

25. The optoelectronic component according to claim 17, wherein the frame is diffusely reflective for the primary radiation.

26. The optoelectronic component according to claim 17, wherein an outer surface of the bonding agent has a convex or concave shape.

27. The optoelectronic component according to claim 17, wherein the bonding agent between the conversion element and the semiconductor chip has a thickness of at most 3 micrometers.

28. The optoelectronic component according to claim 17, wherein the frame has a width of at least 20 micrometers and at most 50 micrometers.

29. The optoelectronic component according to claim 17, wherein the semiconductor chip is arranged on a connection carrier.

30. The optoelectronic component according to claim 17, wherein the contact point is contacted by a wire connection.

31. A method for producing an optoelectronic component, the method comprising:
providing a radiation emitting semiconductor chip for emitting electromagnetic primary radiation from a radiation exit surface;
providing a conversion element for converting the primary radiation into electromagnetic secondary radiation, wherein the conversion element has a frame covering side surfaces of a conversion segment;
applying a bonding agent to the radiation exit surface of the semiconductor chip; and
applying the conversion element to the bonding agent,
wherein a contact point of the semiconductor chip projects beyond the conversion element in an edge region of the semiconductor chip in lateral directions, and
wherein the bonding agent is partially displaced by the conversion element and covers an outer surface of the frame and the contact point of the semiconductor chip in places.

32. The method according to claim 31, further comprising applying a potting over the semiconductor chip and/or the conversion element by film assisted injection molding.
